(19) United States
(12) Patent Application Publication
(10) Pub. No.: US 2006/0191566 A1
(43) Pub. Date: Aug. 31, 2006

(54) Solar concentrator system using photonic engineered materials

(75) Inventor: David Thomas Schaafsma, Fallbrook, CA (US)

Correspondence Address: David Schaafsma, 744 Stewart Canyon, Fallbrook, CA, 92028, US

(73) Assignee: APPLIED OPTICAL MATERIALS

(21) Appl. No.: 11/360,132

(22) Filed: Feb. 22, 2006

Related U.S. Application Data
(60) Provisional application No. 60/656,699, filed on Feb. 28, 2005.

(51) Int. Cl. H02N 6/00; H01L 31/042

(52) U.S. Cl. 136/246

(57) ABSTRACT

A non-imaging optical collecting and concentrating apparatus for use in i.e., optical communications, passive lighting, and solar power applications that is relatively immune from optical incidence angle(s) and therefore does not need to track the movement of the sun to efficiently collect and concentrate optical energy. The apparatus includes a non-planar support structure having a source-facing entrance and an energy-outputting exit. An interior surface of the structure includes a scattering, reflecting and/or diffractive medium such as a photonic bandgap structure to enhance the collection and concentration efficiency.

### CROSS REFERENCE TO RELATED APPLICATIONS

This application claims the benefit of U.S. Provisional Patent Application No. 60/656,699 filed Feb. 28, 2005.

### FIELD OF THE INVENTION

This invention relates generally to the fields of optics, solar energy, and lighting and in particular to an apparatus that efficiently collects and concentrates incident optical energy without the use of imaging devices.

### BACKGROUND OF THE INVENTION

The efficient collection, concentration and distribution of solar energy remain some of the most significant, yet persistent problems of contemporary society. Its importance cannot be overstated. As fossil fuels continue to dwindle in supply and contribute to undesirable environmental effects, the importance of solar energy will only increase. Efforts to realize the potential(s) of solar energy—and in particular efforts directed toward the efficient collection and concentration of solar energy—are therefore of great significance.

The prior art has produced a variety of solar energy collectors and concentrators having a solar energy receiver upon which solar energy to be collected is directed, where only a portion of the receiver surface has solar energy directed upon it at a particular instant. Losses result from those portions of the receiver surface(s) which do not have solar radiation directed thereupon.

For example, one type of solar collector is the familiar parabolic mirror which directs radiant energy incident thereon to a particular point or focus. Such a mirror is usually stationary and—due to the motion of the sun—the focus will move over a particular path each day. As a result, the prior art positioned receivers to cover the particular focus path(s), and only those portions of the receiver(s) upon which the focus was incident would actually be affected by the incident energy.

U.S. Pat. No. 4,052,976 which describes a Non-Tracking Solar Concentrator With a High Concentration Ratio attempted to address a number of the problems inherent in the art by providing a plurality of energy absorbers at the focus of a parabolic reflector. The absorbers were positioned so that the focus, which moved as the sun moved, was incident on at least one, and ideally no more than two, of the absorbers at any one instant.

U.S. Pat. No. 4,267,824 describes a Solar Concentrator constructed from relatively thin, flexible material inflatable to an upright position in which it is generally conical in shape, convergent from its upper to lower end. The inflated device includes a transparent top and a highly reflective inner conical surface which reflects downwardly and thereby concentrates radiant energy.

In U.S. Pat. No. 3,964,464, V. J. Hockman describes a Solar Radiation Collector and Concentrator made from metallic aligned curved reflectors which are used to channel solar radiation to heat a cylindrical tube. The reflectors described are aligned in a general east-west orientation so that concentrated solar radiation moves along the tube during the day and heat is captured without diurnal tracking mechanisms.

More recently, somewhat complex arrangements have been described, such as the Solar Radiation Concentrator and Method of Concentration Solar Radiation which was disclosed in U.S. Pat. No. 6,820,611 which issued to M. Kinoshita on Nov. 23, 2004. In particular, the patentee therein describes a plurality of reflectors disposed on reflector arrangement surfaces and a plurality of reflector vertical bars, connected to the plurality of reflectors in addition to a number of motion members that perform motions along various routes according to variations in the incident angle of the incident solar radiation.

Finally, G. A. Rosenberg discloses a Device For Concentrating Optical Radiation in U.S. Pat. No. 6,274,860 which issued on Aug. 14, 2001. More specifically, the optical radiation concentrating device comprises a holographic planar concentrator including a planar, highly transparent plate and at least one multiplexed holographic optical surface mounted on a surface thereof. The multiplexed holographic optical film has recorded thereon a plurality of diffractive structures having one or more regions which are angularly and spectrally multiplexed. The recording of the diffractive structures is tailored to the intended orientation of the holographic planar concentrator and at least one solar energy collecting device is mounted along at least one edge of the holographic planar concentrator.

Despite these developments however, there exists a continuing need for optical collecting and concentrating structures providing high efficiency, while eliminating the need to track the source of the optical energy. Such structures would represent a significant advance in the art.

### SUMMARY OF THE INVENTION

I have developed, in accordance with the principles of the invention, an optical collecting and concentrating apparatus for use in i.e., passive lighting, solar power, and optical communications applications. In sharp contrast to prior art devices, my inventive collector and concentrator is a non-imaging device. Consequently it is relatively immune from solar (or other optical source) incidence angles and therefore does not need to track the movement of the sun to efficiently collect and concentrate solar energy.

### BRIEF DESCRIPTION OF THE DRAWINGS

A more complete understanding of the present invention may be realized by reference to the accompanying drawing in which:

FIG. 1 shows a perspective view of an optical collection and concentration system including a photonic device constructed according to the teachings of the present invention;

FIG. 2 is a schematic diagram showing the principle of operation of the photonic device of FIG. 1;

FIG. 3 is a schematic diagram showing light at oblique azimuth angles traversing the photonic structure such as that of FIG. 2, and its subsequent collection and coupling, and a comparison with prior art in which similar rays are not collected;

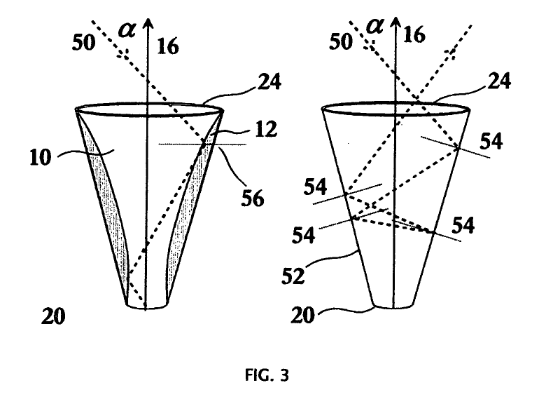

FIG. 4 is a conceptual diagram depicting one potential method for making a structure such as described herein;

FIG. 5 is a schematic diagram of a potential method for reducing end losses in the photonic medium;

FIG. 6 is a graph of the theoretical efficiency of a device using a structure designed according to the principles described herein, showing the various angular efficiencies for different total reflection efficiency of the photonic medium;

FIG. 7 is a graph of the theoretical efficiency of a device using a structure designed according to the principles described herein, with higher loss per pass, illustrating the collection properties of a device constructed with less than optimal performance.

### DETAILED DESCRIPTION

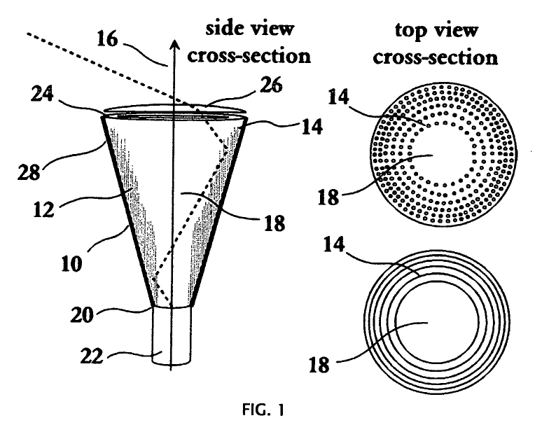

FIG. 1 shows a perspective view of a passive optical collection system constructed according to the present invention. More specifically collector cone 10 includes an optical scattering medium 12 disposed therein. This medium is designed to partially scatter, reflect, or diffract light toward the center of cone 10, by incorporating small voids (i.e. air or vacuum), dissimilar materials (e.g. different plastics), or other variations 14 in the index of refraction of the medium of cone 10, which may be either hollow or filled, discrete or continuous. These variations may have random spatial variation but are substantially oriented in a direction parallel to the central axis 16 of cone 10, which is surrounded by a clear aperture 18, which may also be hollow or filled. Advantageously, this reflection will track with solar motion so that most of the sunlight captured will continue to fall on an aperture 20 at the base of the cone 10, where it may be coupled into a collection mechanism such as a fiber or fiber bundle 22, or onto a photovoltaic cell or thermal absorber. Overlying the open top of the cone 10 is an optional lens 26 which serves to further direct incident light into the cone 10. While this FIG. 1 depicts a plano-convex overlying lens 26, those skilled in the art will readily appreciate that a Fresnel lens structure(s) or others, would suffice as well. The outer surface of cone 10 may also be coated with a reflective or diffractive material 28 so that light rays not affected by the scattering medium 12 will be reflected back into cone 10.

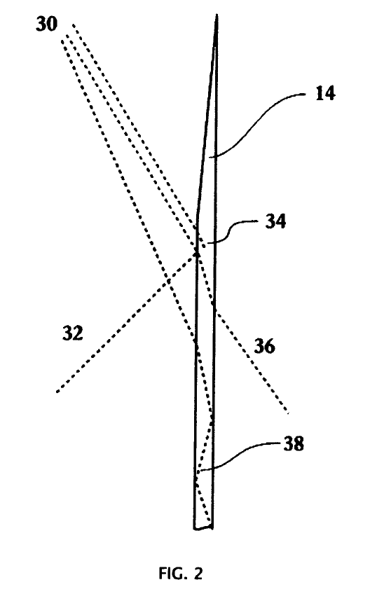

FIG. 2 illustrates the basic physical principle of the scattering medium. After entering cone 10, incident light is directed into the scattering medium 12, where each interaction of a light ray 30 with an individual scattering center 14 consists either of a reflection 32 of light back toward the center of cone 10, a transmission 34 of light through the scatterer, absorption 36 of light by the medium or the interface between media, or a capture and subsequent waveguiding 38 by total internal reflection. The scattering centers 14 may also be continuous either in a radial or circumferential direction or some combination of both. It can be seen that reflection of light from a scatterer 14 which is parallel to the central axis 16 will result in light rays that are directed toward the exit 20 of cone 10, in contrast to reflections from the side of cone 10 which will tend to direct rays of oblique incidence closer to the entrance 24 of cone 10.

It will be apparent to skilled technicians that the scatterers 14 can be distributed throughout the medium 12 in a random fashion, or in regular or quasi-regular physical arrangements. Arranging scatterers 14 with regular or quasi-regular spacing can further be done such that the spacing is either coherent with respect to the incident light or incoherent with respect to the incident light. In the coherent case, the average spacing between scatterers will be less than the coherence length of the light so that light scattered from different scattering centers will combine as coherent electric fields. In the incoherent case, the average spacing between scatterers will be much greater than the coherence length of the light so that light scattered from different scattering centers will combine as incoherent intensity patterns. As an example, a coherent device might be made using transparent diffraction gratings rolled around a central solid structure, or by coating a concentrator cone with layered dielectric films of controlled thickness. An incoherent device might be made using molding or injection techniques with very small features.

In the completely incoherent limit, the concentrating effect will be smaller and the efficiency lower since there will be little interaction either between scatterers at different radii along the same angular direction from the center of the concentrator or between scatterers at similar radii and different angular direction. In the quasi-coherent case, either the angular or the radial average spacing can be reduced below the coherence limit by a plurality of manufacturing methods.

In the completely coherent limit, the scattering centers will form a photonic bandgap structure very similar to that used in photonic crystal fibers or microstructured polymer optical fiber and well known to those skilled in the art. Unlike a photonic crystal fiber, the photonic bandgap concentrator uses the interaction of the geometry of the concentrator itself and the coherent properties of the scattering medium to concentrate light from a large area and large number of modes to a small area and small number of modes. As known from the so-called Lagrange invariant of geometric optics, the conservation of optical path between two media C₁ and C₂ with boundary K is governed by

$${\int }_{{C}_{1}}^{} {n}_{1} {s}_{1} \cdot ⅆ r + {\int }_{{C}_{2}}^{} {n}_{2} {s}_{2} \cdot ⅆ r + {\int }_{K}^{} ( {n}_{2} {s}_{2} - {n}_{1} {s}_{1} ) \cdot ⅆ r = 0 , \qquad ( 1 )$$

where n is the refractive index, and s is the ray vector. The throughput, or the product of angular acceptance and optical aperture, in a non-diffractive optical system is limited by the component with the smallest throughput, so that

$${\int }_{{C}_{1}}^{} {n}_{1} {s}_{1} \cdot ⅆ r {\int }_{{C}_{2}}^{} {n}_{2} {s}_{2} \cdot ⅆ r = 0. \qquad ( 2 )$$

Diffractive optics provide the only means by which this constraint may be relaxed to allow larger angles and areas to be converted to smaller angles and areas, or a larger mode distribution to be condensed into a smaller distribution of degenerate modes.

The concept of a photonic bandgap concentrator (PBC) is shown in FIG. and compared with a device of prior art. Light rays 50 incident at an angle α with respect to the concentrator axis 16 strike the scattering medium 12 in the PBC, or the reflector 52 in the cone of prior art. In a conventional reflective device, even one where the reflector is made from dielectric materials, these incident rays will reflect strongest at specular angles determined by the angle of incidence of the ray relative to the surface normal 54 of the reflector. This will result in oblique rays being redirected out through the entrance 24 of the cone 10. In the PBC, the scattering medium 12 may be represented for simplicity as a single surface, with either diffractive or quasi-coherent reflective properties. If diffractive, the angle at which rays leave the surface will be determined by grating properties and by the incident angle α. If reflective, the reflected ray will return at an angle relative to the plane normal 56 of the scattering medium 12. In both cases, the angle of the reflected ray will be larger than in the purely reflective case. If the surface of the cone is made to reflect in this fashion, using dielectric reflectors or scatterers whose planes are parallel to the axis of the cone, for example, then oblique incident rays will be steered toward the exit of the cone 20 rather than the entrance 24.

As is known from the theory of dielectric reflectors and Bragg gratings, the angular and spectral characteristics of the grating can be controlled over a very wide range by control of material parameters such as the duty cycle of the index variation, the shape of the variation or scattering centers, the magnitude of index variation, and other properties such as long-range variations (e.g. chirp or apodization). Realistic dielectric omnidirectional reflectors have been investigated previously, as documented in the scientific literature, but there have been few applications in the visible spectral region, and no reports of such structures on flexible or curved surfaces. In prior art, the orientation of the planes of a layered dielectric reflector is typically aligned with the geometry of the device; for example, optical waveguides using omnidirectional coatings have the layers of the dielectric oriented parallel to the walls of the cylindrical guide. By orienting the planes of a layered dielectric at an angle to the sides of the cone, the incident light can be guided in much the same fashion while being concentrated to a smaller aperture. Strict coherence is not required, since even in the incoherent limit, a structure with 60 layers and 5% reflection per plane will reflect 96% of the incident light. Coherence of varying degrees will improve these figures commensurately. A semi-coherent reflector made from layers of partial reflectors of 20% reflectivity would require only 20 such layers to achieve 99% reflectivity. It is well known that the absorptive loss of such dielectric or photonic bandgap materials is far superior to even the best metallic reflectors, so that a reflective or diffractive structure made using this approach will have very low loss as well.

In my inventive method, the geometry of the concentrating device can be optimized to work with the diffractive or semi-coherent properties of these structures. Existing photonic crystal fiber or microstructured optical fiber typically cannot take advantage of engineered diffractive properties since the orientation of the channels or voids in the fiber is determined by the drawing of the fiber. My inventive approach allows for a simple concentrating geometry such as a cone, paraboloid, or exponential, to be made from diffractive dielectric materials where parameters such as the orientation, shape, and spacing of the scattering surfaces are designed to work with the geometry of the device for concentrating optical radiation.

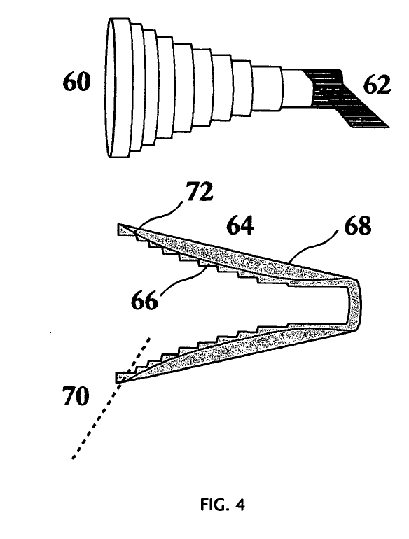

FIG. 4 shows a potential method of fabrication of such a device, wherein a conic shape 60 serves as a preform on which the scattering/diffractive medium 12 will be overlaid. This preform 60 may be either solid or hollow, and may be wrapped, coated, dipped, sprayed, or otherwise caused to have a scattering or diffractive or partially coherent reflecting exterior constructed on it. Alternately, the preform may serve simply to allow sections 62 of the scattering medium to be wrapped or layered, and then after removing preform 60, the formed medium 64 may be trimmed or polished or otherwise finished to the desired specifications. This construction allows the principal planes of the diffractive material to be oriented substantially along the direction of the axis of the cone 10, or in a direction perpendicular to it, or any combination of the two. The various layers or periodic regions of the scattering medium may further be variably spaced, apodized, chirped, or otherwise arranged to optimize spectral, polarization, or angular response. Since circles and ellipses have a very poor fill factor, it is desirable for power generation applications to look at other surface of rotation geometries such as rectangles and hexagons. Since much of the analysis given above applies to two dimensional problems or three-dimensional problems with full azimuthal symmetry, it may be expected that these geometries will behave very similarly to the round conics.

This type of construction also allows the interior profile of the scattering medium 66 to be different from the exterior profile of the concentrator 68. Thus the exterior shape of the concentrator may be a straight sided cone, for example, while the boundary 66 between the clear section 18 inside the cone and the scattering medium 12 may be described by, e.g., an exponential curve. This design consideration is particularly important in optimizing the effective aperture of the device at various incidence angles, where it is undesirable to have rays incident on the scattering medium from the direction of the nearest side of the cone, as indicated by ray 70. The interior profile may also be designed so that the leading edge 72 of the scattering medium has specific reflective or diffractive properties. Such designs may include a random or pseudorandom variation in layer endpoint to suppress coherent reflections, or structured variations designed to reflect coherently in a preferred direction, such as toward the center of the cone.

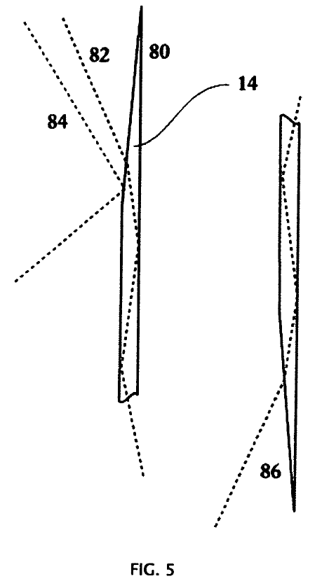

Individual layers or scattering centers may also be designed to promote reflection or scattering or diffraction in preferential directions. One such construction is illustrated in FIG. 5, where the end of a void 14 is shown with a tapered section 80. This taper may angled, for example by shaping a preform before drawing or by cutting a drawn sheet of voids at an angle, such that the angle of the taper tends to either reflect light rays 82 back toward the center of the cone, or to guide light rays 84 by internal reflection (in the case of a void, where the index will by assumption be lower than the surrounding medium). In the latter case, the distal end of the void (closer to the exit aperture) may have a similar taper 86 so that light refracts out of the void toward the center of the cone.

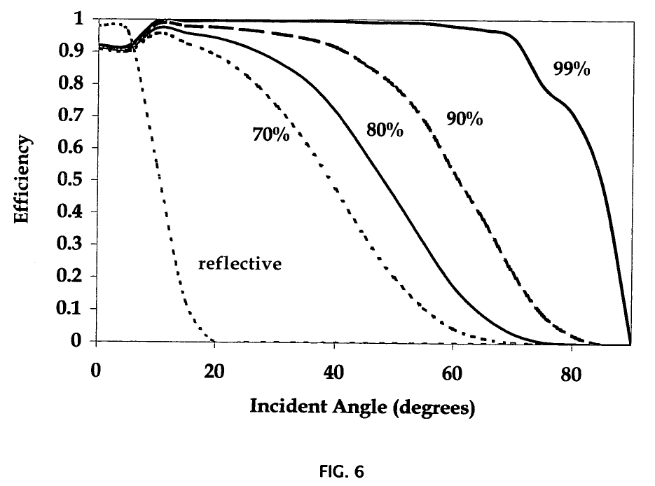

These effects may all combine to yield a very efficient light collector/concentrator, with broad angular response. FIG. 6 shows the theoretical efficiency for a simple cone structure with a vertically-oriented scattering medium as described above, with different values of net reflectivity for the scattering medium, loss of 0.1%, and a metallic reflector on the exterior of the cone with net reflectivity of 90%. It is apparent that the overall efficiency and angular response of the scattering structure I have described is improved greatly versus a purely reflective device of prior art.

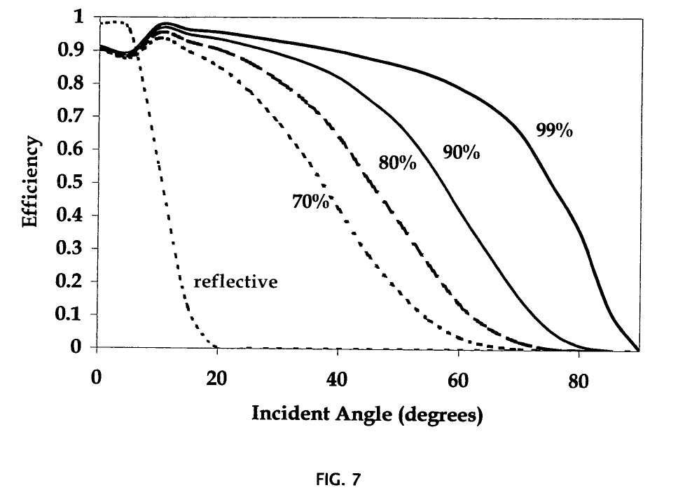

Even with a relatively large loss of 2% per pass, as shown in FIG. 7, the angular response remains considerably wider than for a conventional reflective device. While a 2% surface loss may be quite good for metallic reflectors, for dielectrics the loss will be limited primarily by scattering. Even for extruded materials, high surface quality is achievable, and losses of much less than 2% can be expected.

At this point, while I have discussed and described my invention using some specific examples, those skilled in the art will recognize that my teachings are not so limited. Accordingly, my invention should be only limited by the scope of the claims attached hereto.

What is claimed is:

1. An apparatus for collecting solar or other optical radiation comprising:
a curved support structure, defining an interior surface; and
a scattering medium, disposed throughout a part of the interior of the curved support structure;
such that light rays striking the interior of the curved support structure are directed to a common point, said common point being substantially a focal point of the curved surface.

2. The apparatus of claim 1, where the scattering medium is one of or a combination of the following: layered dielectrics, layered partial reflectors, layered diffraction gratings, or a regular or quasi-regular arrangement of voids or discontinuities in the index of refraction.

3. The optical apparatus of claim 2, wherein the arrangement of the planes of a layered scattering medium are oriented in a direction non-parallel to the exterior surface of the curved support structure.

4. The optical apparatus of claim 2, wherein the diffraction grating has between 100 and 2000 grating lines/mm, is blazed or otherwise engineered such that the diffraction to the common point is enhanced, or is a binary or step grating having a set of step width, height, and/or spacing variations.

5. The optical apparatus of claim 2, wherein the layered reflector has omnidirectional reflectivity between 1 and 100%, and is designed for reflection in the visible spectrum.

6. The optical apparatus of claim 2, wherein the scattering medium is made from voids in a transparent medium or high index inclusions in a lower index medium or low index inclusions in a higher index medium, and the diameter of such voids or inclusions is between 0.1 and 10 times the wavelength of light being collected by the apparatus.

7. The optical apparatus of claim 2 further comprising a lens or transmission grating, overlying the curved support structure.

8. The optical apparatus of claim 2 wherein the curved support structure is one selected from the group consisting of: a conic parabolic concentrator (CPC), a simple power series concentrator including cubic, quartic, or quintic; a conic exponential concentrator (CEC), a conical shaped concentrator, a straight cone shaped concentrator, a bulb shaped concentrator, and mixed-geometry shaped concentrators, and the interior profile of the scattering medium may be chosen from a similar group.

9. A method of collecting solar or other optical energy comprising the steps of:
receiving the optical energy on a substantially non-planar structure having a scattering, partially coherent, coherent reflecting, or diffractive surface for receiving the optical energy;
scattering, reflecting, coherently reflecting, or diffracting the optical energy to a collecting point or any combination of these effects; and
collecting the optical energy into a collector positioned at the collecting point.

10. The method of claim 9 further comprising the steps of reflecting a portion of the solar energy toward the collecting point.

11. The method of claim 9 wherein said scattering, reflecting or diffracting step is performed through the effect of a diffractive grating as described in claim 4, or by a coherent reflector or layered dielectric or an incoherent combination of such reflectors as described in claim 5, or by an arrangement of voids or inclusions as described in claim 6.

12. The method of claim 9 further comprising the steps of focusing or directing, through the effect of a lens or transmission grating positioned between the non-planar structure and the optical energy, the optical energy into/onto the scattering/reflecting/diffracting surface.

13. The method of claim 9 wherein the curved support structure is one selected from the group consisting of: a conic parabolic concentrator (CPC), a simple power series concentrator including cubic, quartic, or quintic; a conic exponential concentrator (CEC), a conical shaped concentrator, a straight cone shaped concentrator, a bulb shaped concentrator, and a mixed-geometry shaped concentrator and the interior profile of the scattering medium may be chosen from a similar group.

14. An optical collector/concentrator comprising:
a curved, means for supporting a scattering/reflective/diffractive surface wherein said curved supporting means defines an interior surface; and
a means for preferentially directing light rays, disposed upon the supporting means of the curved support structure;
such that light rays striking the interior surface of the curved support means are directed to a common point, said common point being substantially a focal point of the curved support means
